(19) United States
(12) Patent Application Publication
(10) Pub. No.: US 2006/0211167 A1
(43) Pub. Date: Sep. 21, 2006

(54) METHODS AND SYSTEMS FOR IMPROVING MICROELECTRONIC I/O CURRENT CAPABILITIES

(75) Inventors: John U. Knickerbocker, Wappingers Falls, NY (US); Hai P. Longworth, Poughkeepsie, NY (US); Roger A. Quon, Rhinebeck, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 10/907,062

(22) Filed: Mar. 18, 2005

(51) Int. Cl. H01L 21/00; H01L 23/02

(52) U.S. Cl. 438/106; 257/678

(57) ABSTRACT

Disclosed are microelectronic structures based on improved design and material combinations to provide improved current capabilities per I/O. The preferred embodiment of the invention uses a combination of one or more of the following: (1) Underbump metallurgy which enhances current per I/O by increasing via diameter or by having multiple via openings under BLM; (2) Thicker underbump metallurgy, where use of good conductor metallurgies can be used with increased thickness; (3) Utilizing larger via diameter under bump metallurgy, larger solder bump diameter and/or other current enhancing features for power and/or ground via connections; and (4) Using additives in Pb-free alloys to alter microstructure to minimize migration of atoms in the solder or at intermetallic transitions.

### BACKGROUND OF THE INVENTION

1. Field of the Invention

This invention generally relates to microelectronic devices, and more specifically, the invention relates to improving the current capabilities of the I/O connectors of microelectronic devices.

2. Background Art

In the manufacture of microelectronic devices, a semiconductor structure is electrically joined to a chip carrier, such as a ceramic substrate or a printed circuit board. While various procedures are known for making these interconnections, one procedure that has achieved widespread use is area array interconnections introduced by IBM and referred to as Controlled Collapse Chip Connection, or C4.

C4 technology, which was developed by IBM in the 1960s, offers many advantages. One advantage is the high input/output density of the C4 process, which enables solder bumps to be placed anywhere on the chip so that it is easier to make connections to the circuitry at those joints. In addition, short solder bumps improve the overall electrical performance and allow more control over the size of the chip. Further, C4 technology offers a self-alignment feature whereby the surface tension of the solder allows the solder balls to form self aligned metallurgical joints with the substrate.

C4 technology provides flip chip connections between semiconductor devices and substrates. Cylindrical C4 solder bumps are formed above an insulation layer and above the exposed surfaces of connector pads, each of which is exposed through a via hole in the insulation layer. Subsequently, the C4 solder bumps are heated above their melting point until the solder bumps wet or join to the adjoining pads using a reflow controlled collapse chip connections or “C4” solder balls. The actual C4 solder bumps may be fabricated using a number of different processing techniques, including evaporation, screening, and electroplating.

The first fundamental operation in forming C4 solder bumps by electrolytic means is to deposit a continuous stack of metal films across the wafer to be bumped. These films include a conduction film that performs a dual function. First, it provides a conductive path for current flow during the electrolytic deposition of the C4 solder bumps. Second, the conductive metal remains under the C4 solder bumps and forms the basis for the Ball Limiting Metallurgy (BLM) underneath the solder balls, which is a key component in defining the field reliability of the device. In addition, the BLM layers may contain barrier layers that prevent the solder from detrimentally interacting with the underlying device constituents.

Heretofore, conventional C4 technology typically employs a lead-tin (Pb/Sn) alloy for electrically joining the semiconductor device to the chip carrier. Recently, however, there has also been a focus on the use of Pb-free solder alloys.

The higher power needed to support next generation, advanced chip technology requires more current in the same or smaller I/O connections. Also, the use of Pb-free solders and smaller feature size connections to chip can limit current due to the lower melting temperature of Pb-free solder alloys and reduced diameter of solder connection. Thus, limitations of existing solutions will not meet the increased current demand of next generation chip technologies.

### SUMMARY OF THE INVENTION

An object of this invention is to provide improved current capabilities per I/O of microelectronic devices.

Another object of the invention is to improve design and material combinations of the I/Os of microelectronic devices to obtain improved current capabilities per I/O.

A further object of the present invention is to provide improved current capabilities per I/O as well as the opportunity to have mixed I/O sizes to differentiate between power and ground connections needing larger dimensions to carry more current and smaller connections for signal I/O.

These and other objectives are attained with new structures based on improved design and material combinations to provide improved current capabilities per I/O as well as the opportunity to have mixed I/O sizes to differentiate between power and ground connections needing larger dimensions to carry more current and smaller connections for signal I/O.

The preferred embodiment of the invention, described below in detail, uses a combination of one or more of the following:

Underbump metallurgy which enhances current per I/O by increasing via diameter of opening under BLM or by having multiple via openings under BLM so the via does not limit current or lead to either electrical or thermal migration and failure in operation.

Thicker underbump metallurgy, where use of good conductor metallurgies such as copper, copper alloys (CuNi, CuSn, or other alloys), copper and nickel or nickel can be used with increased thickness to enhance current carrying capability and limit current crowding.

Opportunity to utilize larger feature of via diameter under bump metallurgy, larger solder bump diameter and/or other current enhancing features for power and/or ground via connections compared to signal interconnections.

Utilization of additives in Pb-free alloys to alter microstructure to minimize migration of atoms in the solder or at intermetallic transitions by the addition of small quantities of dopants or impurities to the Pb-free alloys. These dopants or impurities may also be added to any structure which may be limiting current capability such as a via under underbump metallurgy.

The present invention may be used with multiple metallurgies, such as TiW, CrCo, Cu and Ni, in BLM to reduce electromigration. Ni may be used to enhance structure from electromigration perspective. It is expected that other combination of BLM metallurgies, such as Ti Cu Ni, can also be used as enhancements. Ti Cu Ni is superior to Ti Cu when used with eutectic or Pb-free solder. Other surface metallurgies (perhaps cobalt and others), which would be in contract with solder, can also enhance electromigration.

Further benefits and advantages of the invention will become apparent from a consideration of the following detailed description, given with reference to the accompanying drawings, which specify and show preferred embodiments of the invention.

### BRIEF DESCRIPTION OF THE DRAWINGS

FIGS. 1 and 2 illustrate a conventional process for manufacturing one or more solder bumps and forming one or more solder balls therefrom on a semiconductor device.

FIGS. 3 and 4 show the use of an increased via diameter to improve microelectronic I/O current.

FIGS. 5A and 5B illustrate the use of multiple vias to improve microelectronic I/O current.

FIGS. 6 and 7 show, respectively, a polycrystal and a single crystal structure.

FIG. 8 illustrates how current may enter a solder interconnect from multiple points.

FIGS. 9 and 10 show the use of thicker underbump metallurgy to improve microelectronic I/O current.

FIG. 11 shows the clustering of solder bumps.

### DETAILED DESCRIPTION OF THE PREFERRED EMBODIMENTS

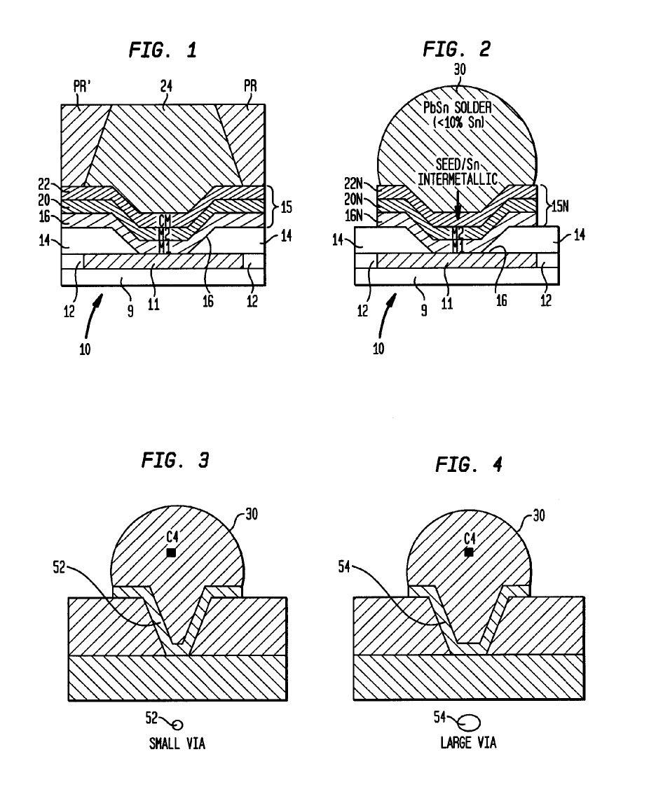

FIGS. 1 and 2 illustrate a prior art process for manufacturing one or more C4 solder bump(s) 24 and forming one or more C4 solder balls 30 therefrom on a conformal, seed layer stack 15 formed above a metal contact 1I1 formed on a semiconductor device 10. The seed layer stack 15 is composed of a base of at least one metal adhesion layer 16. As shown in FIGS. 1 and 2, the device 10 includes a base of two metal layers 16 and 20. To complete the seed layer stack, the metallic base layers 16 and 20 are covered by a conductive metal (CM) layer 22, that is composed of copper (Cu). A portion of the semiconductor device 10 is shown to illustrate an example of a C4 bumping process sequence in which the seed layer stack 15 is used during processing. As will be explained below, after processing only a portion of the copper originally included in CM layer 22 remains in CM layer 22N as a part of the seed layer stack 15 of layers 16N, 20N and 22N in FIG. 2.

The device 10 on which the seed layer stack 15 and the C4 solder bump 24 are formed includes a lower insulator layer 12 in which the metal contact 11 has been formed. The metal contact 11 is partially covered by a second insulator layer 14 through which a tapered via hole has been formed exposing a portion of the top surface of the metal contact 11. The seed layer stack 15 is formed on the surfaces of the second insulator layer 14 and the exposed portion of the top surface of the metal contact 11. The C4 solder bump 24 is formed over the seed layer stack 15 in an opening formed in a photoresist mask PR.

The series of process steps used to fabricate structures in FIGS. 1 and 2 begins with a partially formed device 10 which includes the planar contact 11 and the lower insulation layer 12, which have been formed on the surface of a substrate 9, such as a silicon wafer (as shown) or a dielectric layer formed thereabove, as will be well understood by those skilled in the art. The contact and the lower insulation layer 12 are shown as having upper surfaces which are formed in a single plane. An upper insulation layer 14 is formed covering both a portion of the planar contact 11 and the lower insulation layer 12 with a tapered via hole opening through the upper insulation layer 14, exposing a portion of the top surface of the contact 11.

FIG. 1 illustrates the fully deposited device 10 prior to the removal of the photoresist mask PR′ and the superfluous, peripheral portions of the CM layer 22 composed of copper (Cu), the M2 layer 20, and the M1 layer 16 aside from the C4 solder bump 24.

FIG. 2 depicts the final device 10 after the removal of the photoresist mask PR, removal of the peripheral portion of seed layer stack 15 leaving a narrower BLM pad 15N, and reflowing of the C4 solder bump 24 to form the C4 solder ball 30.

The present invention is directed to improving the microelectronic current through the I/O connections formed from solder balls 30. Generally, this is based on improved design and material combinations to provide improved current capabilities per I/O as well as the opportunity to have mixed I/O sizes to differentiate between power and ground connections needing larger dimensions to carry more current and smaller connections for signal I/O.

### PREFERRED EMBODIMENT OF THE INVENTION

Underbump metallurgy which enhances current per I/O by increasing via diameter of opening under BLM or by having multiple via openings under BLM so the via does not limit current or lead to either electrical or thermal migration and failure in operation. For example, for connections of approximately 100 um to 125 um diameter bump, via diameter presently used is of about 47 um to greater than 58 um for voltage and ground vias under bump metallurgy.

Thicker underbump metallurgy, where use of good conductor metallurgies such as copper, copper alloys (CuNi, CuSn, or other alloys), copper and nickel or nickel can be used with increased thickness to enhance current carrying capability and limit current crowding. For bumps of 100 um to 125 um diameter, underbump metallurgy thickness for ground and power vias may be increased from less than 0.5 um to 2 um to be greater than 2 um to 5 um.

Opportunity to utilize larger feature of via diameter under bump metallurgy, larger solder bump diameter and/or other current enhancing features for power and/or ground via connections compared to signal interconnections.

Utilization of additives in Pb-free alloys to alter microstructure to minimize migration of atoms in the solder or at intermetallic transitions by the addition of small quantities of dopants or impurities to the Pb-free alloys. These dopants or impurities may also be added to any structure which may be limiting current capability such as a via under underbump metallurgy. For solder such as SnCu, SnAgCu, SnAg and AuSn or other Pb-free solders, additives such as Bismuth or Antimony, or other additives may added to the solder. For small features of copper in via or for intermetallics that may form between solder and adjacent features, impurities such as Zr, Ti, Mg or other impurities in quantities of less than 5 percent can significantly impede electromigration and thus permit much higher current capability for small structure sizes.

Each of these ways to improve microelectronics I/O current is discussed below in more detail.

I. Increase the Via Diameter, or have Multiple Via Openings Under BLM

The mean lifetime (T₅₀) of a C4's is determined by the well-established Black's equation:
T₅₀=A I⁻ⁿ EXP (Eₐ/kT)

where,

A=Constant

I=Pad current

N=Current density exponent (typical value=2)

Eₐ=Activation energy

K=8.62×10−5 eV/K

T=Operating Temperature in Kelvin

1. Increase Via Diameter:

For example but not limited to leaded solder connections (C4s), electromigration has been observed to occur first in solder adjacent to BLMs. Once voids or gaps had been formed, current is carried through BLM via opening. For a given current level, the larger the via opening, the lower is the current density and hence the more electromigration resistant.

For example, with reference to FIGS. 3 and 4, if the via diameter increases, as represented at 52 and 54, from 40 um to 60 um, for a given current level, the current density decreases by a factor of 2.25× and electromigration lifetime increases by a factor of 5. Therefore, enlarging BLM via will allow C4 to carry a higher amount of current.

A ratio of minimum via diameter crass-section area to BLM bump diameter is important in the relative current carrying capability of the interconnection and thus can be calculated to support respective larger or smaller via sizes, BLM diameters and current carrying capability/time to meet wide range of applications. Basically, for leaded C4, current carrying capabilities were found to scale with current density across the via diameter and not the current density across the solder ball diameter, so the larger the via, the better the property. The preferred ratio is 1 but due to processing limitations and the need to have the BLM as an effective barrier to prevent solder interaction with chip metallurgy, there is a maximum supportable diameter for a particular BLM metallurgy/process. Thus, for example, for leaded C4s, the larger a via which could be processed the better.

2. Multiple Via Openings Under BLM:

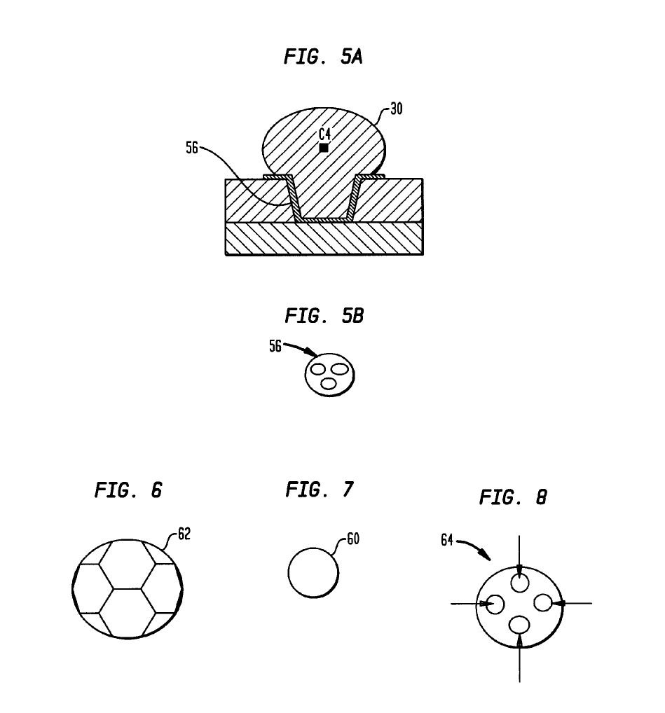

If process limitation precludes the opening of a very large via, the alternate way to increase via areas to reduce current density is the use of multiple via openings under BLM, as illustrated, for example at 56, in FIGS. 5A and 5B.

Electromigration damages first occur as small voids along grain boundaries (electromigration paths in typical polycrystalline material). Electrical opens occur when the voids link together forming a continuous gap. The use of multiple via openings 56 will lessen the chance for continuous gap formation, thus increasing device electromigration lifetime and can be due to increased cross sectional area for multiple vias, similar to the discussion above for larger via diameter, which helps to support a higher amount of current.

In addition, with proper heat treatment and material selection, replacing one large via with multiple small vias will increase the probability of having a single large grain spanning across a via opening. With reference to FIG. 6 and 7, single-crystalline 60 electrical conductors are known to be much more electromigration resistant than polycrystalline 62 conductors since grain-boundary diffusion is replaced by lattice diffusion (with higher activation energy). An additional option for improved electromigration resistance is to create desired single grain features based on material choice, controlled processing parameters and/or heat treatments.

Use of multiple vias under the BLM can also minimize the effect of current crowding at the chip-solder interface; current crowding can effectively increase the localized current density, leading to an acceleration in electromigration failures.

This embodiment of the invention aids the distribution of current at the BLM-via interface, negating the effect of current crowding, as shown at 64 in FIG. 8.

FIG. 8 illustrates how current enters the solder interconnect from four points. In this manner, localized stress due to electrical current is uniformly distributed on the BLM

II. Use Thicker Underbunp Metallurgy

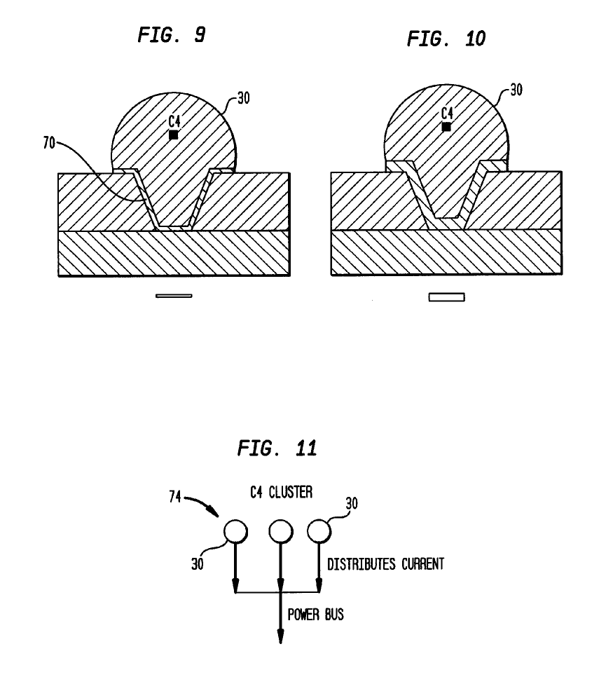

With reference to FIGS. 9 and 10, the use of thicker underbump metallurgy, represented at 70, especially for a specific metal layer which is more susceptible to electromigration-induced depletion, will make the C4 bumps become more electromigration resistant and thus capable of carrying higher current:

In addition, use of one or more metallurgies used by choice of current carrying capability and electrical resistivity value can provide improved current distribution between under bump metallurgy electrical connections or straps and solder connections depending on geometric features used in the structure.

III. Current Enhancing Features for Power and/or Ground Connections

With advancing device technologies requiring higher device densities and tighter groundrule, selective design of electromigration-enhanced features (larger vias, multiple vias, larger metal pad to capture large vias etc.) is required. Factors to take into consideration include: 1) the direction of electron flows (power or vdd for positive C4s which are more susceptible to electromigration and ground for negative C4s which are less susceptible); 2) amount of required current: signal C4s typically carry much lower current and therefore do not require robust, large features as with power and ground C4s; and 3) degree of redundancies: clusters of ground or power C4s to share current loads should be designed in areas requiring high power densities, as can be seen from FIG. 11.

Therefore, use of more than one size, for example solder diameter, interconnection feature can be advantageous to support a benefit for those interconnections with greatest current carrying ability while other interconnections not requiring high levels of current can remain at a smaller size.

This embodiment, illustrated at 74 in FIG. 11, enhances high electrical performance demanded by devices within the material limitations of the solder systems. It may be noted that electromigration performance generally scales with the melting point of the solder, so a device using a high-melt, 97/3 PbSn solder might be expected to have an electromigration lifetime an order of magnitude longer than a equivalent device built with a SnAgCu, lead-free solder. Redesigning the device to accommodate the bump schemes described above (the clustering of lead-free bumps, or selectively enlarging high-current bearing bump) permits one to use a desired material set (lead-free in this instance) while also maintaining or improving electromigration reliability.

IV. Use Additives

In typical polycrystalline C4s, electromigration occurs through grain boundary transport mechanism. The additions of appropriate impurities can help to stuff the grain boundaries, thus retarding electromigration. Additives can also form fine particles or finely dispersed intermetallics which may contribute to a more electromigration resistant structure. Alloy addition can also raise the melting point which is correlated with electromigration resistant property.

The present invention may be used with multiple metallurgies, such as TiW, CrCo, Cu and Ni, in BLM to reduce electromigration. Ni may be used to enhance structure from electromigration perspective. It is expected that other combination of BLM metallurgies, such as Ti Cu Ni, can also be used as enhancements. Ti Cu Ni is superior to Ti Cu when used with eutectic or Pb-free solder. Other surface metallurgies (perhaps cobalt and others), which would be in contract with solder, can also enhance electromigration.

While it is apparent that the invention herein disclosed is well calculated to fulfill the objects stated above, it will be appreciated that numerous modifications and embodiments may be devised by those skilled in the art, and it is intended that the appended claims cover all such modifications and embodiments as fall within the true spirit and scope of the present invention.

What is claimed is:

1. A semiconductor package assembly comprising a substrate, at least one integrated circuit chip mounted on said substrate, and at least one interconnect for connecting the substrate and said integrated circuit chip, and wherein the integrated circuit chip includes a via, the interconnect includes a solder ball extending into the via to help connect the circuit chip and the substrate, and the via has an increased diameter of about at least 55um to increase the electromigration lifetime of the solder ball.

2. A semiconductor package assembly according to claim 1, wherein the via diameter is approximately 60 um.

3. A semiconductor package assembly according to claim 1, wherein the increased diameter of the via decreases the current density by a factor of approximately 2.25.

4. A semiconductor package assembly according to claim 1, wherein the increased diameter of the via increases the electromigration lifetime of the solder ball by a factor of approximately 5.

5. A semiconductor package assembly comprising a substrate, at least one integrated circuit chip mounted on said substrate, and at least one interconnect for connecting the substrate and said integrated circuit chip, and wherein the interconnect includes at least one solder ball, the integrated circuit includes multiple via openings, and said at least one solder ball extends into all of said via openings to help connect the integrated circuit to the substrate, thereby to reduce the current density through said at least one solder ball.

6. A semiconductor package assembly according to claim 5, wherein said multiple via openings lessen the chance for continuous gap formation in the solder ball.

7. A semiconductor package assembly according to claim 5, wherein said multiple via openings increase device electromigration lifetime.

8. A semiconductor package assembly according to claim 5, wherein the multiple via openings help to support a higher amount of current.

9. A semiconductor package assembly according to claim 5, wherein the multiple via openings increase the probability of having a single large grain spanning across the via openings.

10. A semiconductor package assembly according to claim 5, wherein the use of the multiple via openings minimizes the effect of current crowding at the chip-solder interface.

11. A semiconductor package assembly according to claim 5, wherein the chip includes Ball Limiting Metallurgy (BLM) underneath the solder ball, and the multiple via openings aid the distribution of current at the BLM-via interface.

12. A semiconductor package assembly according to claim 11, wherein, because of the multiple via openings, localized stress due to electrical current is uniformly distributed on the BLM.

13. A method of assembling a semiconductor package, comprising the steps of:
using solder bumps to help connect an integrated circuit chip to a substrate; and
providing the integrated circuit with a thicker, greater than 2 um, underbump metallurgy to enhance current carrying capability and limit current crowding.

14. A method according to claim 13, wherein the underbump metallurgy has a thickness greater than 5 um.

15. A method according to claim 13, wherein the underbump metallurgy includes materials selected from the group consisting of: copper, copper alloys, copper and nickel, nickel alloys, copper alloys and nickel alloys, and nickel.

16. A method according to claim 13, wherein the solder bump has a diameter of 100 um to 125 um.

17. A method according to claim 13, wherein the thicker underbump metallurgy makes the solder bump become more electromigration resistant thus capable of carrying higher current.

18. A method according to claim 13, wherein the thicker underbump metallurgy provides improved current distribution between underbump metallurgy electrical connections.

19. A method of designing a semiconductor package to include current enhancing features for power and/or ground connections, the method comprising the step of:
selecting the design of electromigration enhanced features for the connections by considering the following factors:
1. direction of electron flow through the connections;
2. amount of required current through the connections; and
3. degree of redundancy among the connections.

20. A method according to claim 19, wherein said features include one or more of: larger vias, multiple vias, and larger metal pad to capture large vias.

21. A method according to claim 19, wherein the package includes a multitude of solder bumps, and the selecting step includes the step of selecting more than one size for the solder bumps.

22. A method according to claim 21, wherein the step of selecting more than one size includes the steps of:
designing solder bumps requiring high levels of current, to have a larger size diameter; and
designing solder bumps not requiring high levels of current, to have a smaller size diameter.

23. A method according to claim 19, wherein the selecting step includes the step of clustering solder bumps to share current loads in areas requiring high power densities.

24. A method of assembling a semiconductor package, comprising the step of:
using solder bumps to help connect an integrated circuit chip to a substrate, including the step of using a Pb free alloy as a solder, the Pb-free alloy including additives to minimize migration of atoms in the solder or at intermetallic transitions.

25. A method according to claim 24, wherein, in the solder bumps, electromigration occurs through a grain boundary transport mechanism, and
Said additives help stuff the grain boundaries thus retarding electromigration.

26. A method according to claim 25, wherein said additives also form fine particles or finely dispersed intermetallics which contribute to a more electromigration resistant structure.

27. A method according to claim 24, wherein said additives are selected from the group consisting of: Bismuth, Antimony, Zirconium, Titanium and Manganese.

28. A method according to claim 24, wherein said additives comprise less than 5% by weight of the Pb free solder.
